(19) United States
(12) Patent Application Publication
(10) Pub. No.: US 2026/0114024 A1
(43) Pub. Date: Apr. 23, 2026

(54) SEMICONDUCTOR DEVICE WITH STACKED TRANSISTORS

(71) Applicant: TAIWAN SEMICONDUCTOR MANUFACTURING COMPANY, LTD., Hsinchu (TW)

(72) Inventors: Hong-Chih CHEN, Changhua County (TW); Ta-Chun LIN, Hsinchu (TW); Ming-Heng TSAI, Taipei City (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/918,864

(22) Filed: Oct. 17, 2024

(51) Int. Cl. H01L 21/8238; H01L 21/764; H01L 21/822; H01L 27/092; H01L 29/06; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 64/017; H10D 64/018; H10D 84/017; H10D 84/0188; H10D 84/856; H10D 88/01; H10W 10/021; H10W 10/20

(57) ABSTRACT

A method comprises following steps. A first multi-layer stack is formed over a substrate. The first multi-layer stack comprises first semiconductor layers and second semiconductor layers alternating with the first semiconductor layers. A third semiconductor layer is formed over the first multi-layer stack. A second multi-layer stack is formed over the third semiconductor layer. The second multi-layer stack comprises fourth semiconductor layers and fifth semiconductor layers alternating with the fourth semiconductor layers. The third semiconductor layer is replaced with an isolation nanostructure. The first semiconductor layers and fourth semiconductor layers are removed. A first gate structure is formed surrounding the first semiconductor layers. A second gate structure is formed surrounding the fifth semiconductor layers.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an example CFET structure in accordance with some embodiments of the present disclosure.

FIGS. 2-4, 5A, 15C, 16B, 17B, 18B are example cross-sectional views of intermediate stages in the manufacturing of GAA-FETs, which correspond to reference cross-section A-A illustrated in FIG. 1 that extends through a gate region along a longitudinal axis of the gate region.

FIGS. 5B, 6B, 7B, 8B, 9B, 10B, 10C, 10D, 11B, 12B, 13B, 14B, 15B, 16A, 17A, 18A are example cross-sectional views of intermediate stages in the manufacturing of GAA-FETs, which correspond to reference cross-section C-C illustrated in FIG. 1 that extends in a direction of current flow between source/drain regions.

FIGS. 6A, 7A, 8A, 9A, 10A, 11A, 12A, 13A, 14A, and 15A are example cross-sectional views of intermediate stages in the manufacturing of GAA-FETs, which correspond to reference cross-section B-B illustrated in FIG. 1 that extends through source/drain regions along the longitudinal direction of the gate region.

FIG. 19A illustrates an example cross-sectional view of GAA-FETs according to some embodiments of the present disclosure, which corresponds to reference cross-section C-C illustrated in FIG. 1 that extends in a direction of current flow between source/drain regions.

FIG. 19B illustrates an example cross-sectional view of GAA-FETs according to some embodiments of the present disclosure, which corresponds to reference cross-section A-A illustrated in FIG. 1 that extends through a gate region along a longitudinal axis of the gate region.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices (e.g., planar transistors) that may benefit from aspects of the present disclosure.

As scales of the fin width in fin field effect transistors (FinFET) decreases, channel width variations might cause mobility loss. GAA transistors, such as nanosheet transistors are being studied as an alternative to fin field effect transistors. In a GAA transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents. Stacked transistor structures, such as complementary field effect transistors (CFETs) including vertically stacked p-type FETs and n-type FETs, can provide further reduced footprint and density improvement for advanced IC technology nodes (particularly as IC technology nodes advance to 3 nm (N3) and below).

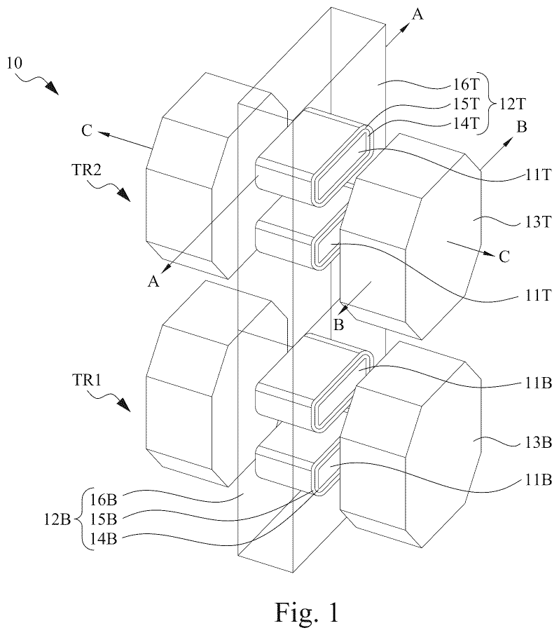

FIG. 1 is a perspective view of an example CFET structure in accordance with some embodiments of the present disclosure. In some embodiments of the present disclosure, a CFET structure includes a first transistor TR1 and a second transistor TR2 vertically stacked over the first transistor TR1, and thus the second transistor TR2 can be interchangeably referred to as a top transistor and the first transistor TR1 can be interchangeably referred to as a bottom transistor. In some embodiments, the first transistor TR1 and the second transistor TR2 are GAA FET transistors. The first transistor TR1 includes first semiconductor channel layers 11B disposed one above another, a first gate structure 12B wrapping around each of the first semiconductor channel layers 11B, and first source/drain epitaxy structures 13B on opposite sides of each of the first semiconductor channel layers 11B. The second transistor TR2 includes second semiconductor channel layers 11T vertically stacked one above another, a second metal gate structure 12T wrapping around each of the second semiconductor channel layers 11T, and second source/drain epitaxy structures 13T on opposite sides of each of the second semiconductor channel layers 11T. The first gate structure 12B may include an interfacial layer 14B, a high-k gate dielectric layer 15B around the interfacial layer, and one or more gate metal layers 16B around the high-k gate dielectric layer 15B. The second gate structure 12T may include an interfacial layer 14T, a gate dielectric layer 15T, and one or more gate metal layers 16T. In some embodiments, the first transistor TR1 has a first conductivity type (e.g., n-type) and the second transistor TR2 has a second conductivity type (e.g., p-type) different from the first conductivity type.

FIG. 1 further illustrates reference cross-sections that are used in later figures. Cross-section A-A is along a longitudinal axis of gate structures 12B, 12T and in a direction, for example, perpendicular to the direction of current flow between the source/drain epitaxy structures 13B of the bottom transistor TR1 and the direction of current flow between the source/drain epitaxy structures 13T of the top transistor TR2. Cross-section B-B is parallel to cross-section A-A and extends through source/drain epitaxy structures 13B of the bottom transistor TR1 and source/drain epitaxy structures 13T of the top transistor TR2. Cross-section C-C is perpendicular to cross-sections A-A and B-B and is parallel to the direction of current flow between the source/drain epitaxy structures 13B of the bottom transistor TR1 and the direction of current flow between the source/drain epitaxy structures 13T of the top transistor TR2. Subsequent figures refer to these reference cross-sections for clarity.

In the CFET scheme as illustrated in FIG. 1, a phenomenon known as the metal boundary effect (MBE) occurs at the interface between the gate layer 16B of the first gate structure 12B and the gate layer 16T of the second gate structure 12T. MBE may arise from the diffusion or intermixing of different metals between the first gate structure 12B and the second gate structure 12T, which can adversely affect their respective work functions. To address this issue, the present disclosure provides, in various embodiments, an isolation layer disposed between the metal layer of the bottom gate structure and the metal layer of the top gate structure. This isolation layer effectively prevents metal diffusion or intermixing between the bottom and top gate structures, thereby mitigating the metal boundary effect.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

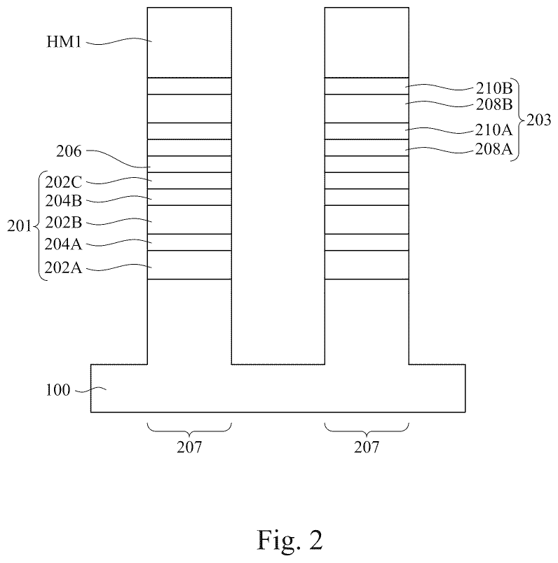

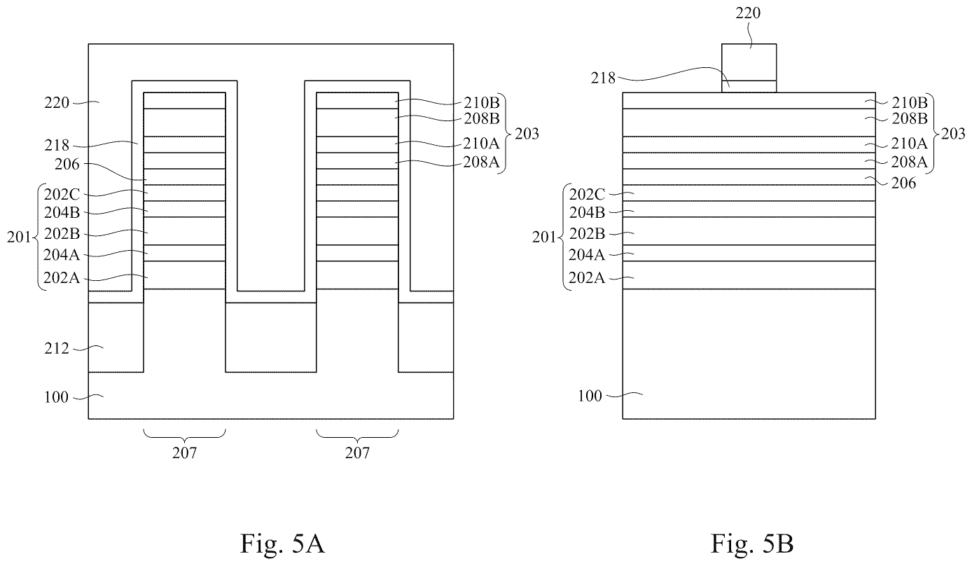

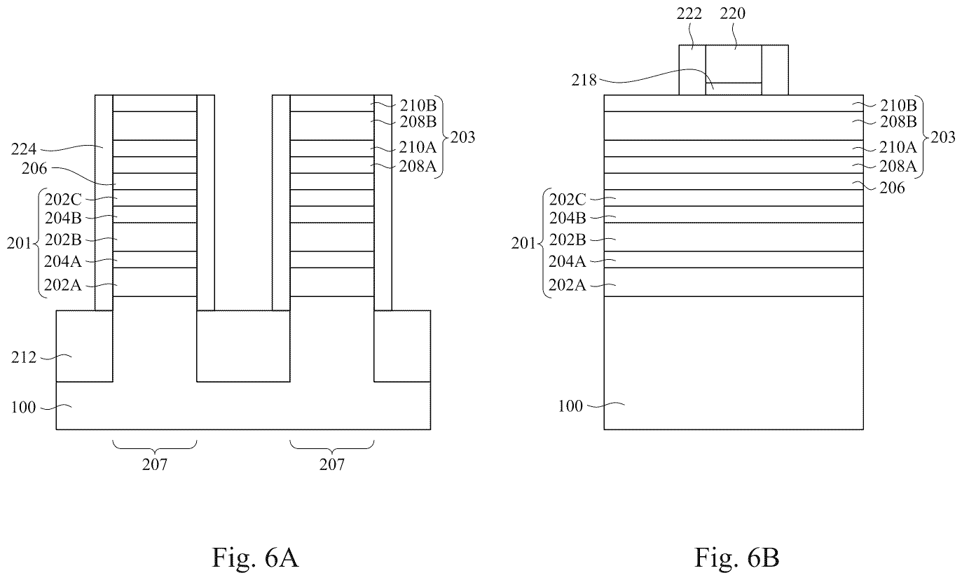

FIGS. 2 through 18B are example cross-sectional views of intermediate stages in the manufacturing of GAA-FETs, in accordance with some embodiments. FIGS. 2-4, 5A, 15C, 16B, 17B, 18B illustrate reference cross-section A-A illustrated in FIG. 1 that extends through a gate region along a longitudinal axis of the gate region. FIGS. 5B, 6B, 7B, 8B, 9B, 10B, 10C, 10D 11B, 12B, 13B, 14B, 15B, 16A, 17A, 18A illustrate reference cross-section C-C illustrated in FIG. 1 that extends in a direction of current flow between source/drain regions. FIGS. 6A, 7A, 8A, 9A, 10A, 11A, 12A, 13A, 14A, and 15A illustrate reference cross-section B-B illustrated in FIG. 1 that extends through source/drain regions along the longitudinal direction of the gate region. It is understood that additional operations can be provided before, during, and after the processes shown by FIGS. 2-18B, and some of the operations described below can be replaced or eliminated, for additional embodiments of the method. The order of the operations/processes may be interchangeable.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a first multi-layer stack 201 is formed over the substrate 100. The multi-layer stack 201 includes alternating layers of first semiconductor layers 202A-202C (collectively referred to as first semiconductor layers 202) and second semiconductor layers 204A-204B (collectively referred to as second semiconductor layers 204). For purposes of illustration and as discussed in greater detail below, the first semiconductor layers 202 will be removed and the second semiconductor layers 204 will be patterned to form channel regions of bottom GAA-FETs.

The first multi-layer stack 201 is illustrated as including three layers of the first semiconductor layers 202 and two layers of the second semiconductor layers 204 for illustrative purposes. In some embodiments, the multi-layer stack 201 may include any number of the first semiconductor layers 202 and the second semiconductor layers 204. For example, the multi-layer stack 201 may include 1, 2, 3, 4 or more than four second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of bottom GAA-FETs, such as silicon, silicon germanium, or the like. In some embodiments, the second semiconductor layers 204 may be formed of a Group IV-based material, a Group III-V-based material, or a Group II-VI-based material.

The first semiconductor layers 202 are formed of a first semiconductor material, and the second semiconductor layers 204 are formed of a second semiconductor material different than the first semiconductor material. The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of bottom GAA-FETs. In some embodiments, the first semiconductor layers 202 are silicon germanium and the second semiconductor layers 204 are pure silicon (Si) having an etch selectivity to silicon germanium. In some embodiments, the first semiconductor layers 202 are silicon germanium and the second semiconductor layers 204 are pure germanium (Ge) having an etch selectivity to silicon germanium.

A third semiconductor layer 206 is then formed over the first multi-layer stack 201. The third semiconductor layer 206 will be subsequently replaced with dielectric isolation structures, which may define the boundary of the bottom GAA-FETs and top GAA-FETs.

A second multi-layer stack 203 is formed over the third semiconductor layer 206. The second multi-layer stack 203 includes alternating layers of fourth semiconductor layers 208A-208B (collectively referred to as fourth semiconductor layers 208) and fifth semiconductor layers 210A-210B (collectively referred to as fifth semiconductor layers 210). For purposes of illustration and as discussed in greater detail below, the fourth semiconductor layers 208 will be removed and the fifth semiconductor layers 210 will be patterned to form channel regions of top GAA-FETs.

The second multi-layer stack 203 is illustrated as including two layers of the fourth semiconductor layers 208 and two layers of the fifth semiconductor layers 210 for illustrative purposes. In some embodiments, the multi-layer stack 203 may include any number of the fourth semiconductor layers 208 and the fifth semiconductor layers 210. For example, the multi-layer stack 203 may include 1, 2, 3, 4 or more than four fifth semiconductor layers 210. Each of the layers of the multi-layer stack 203 may be epitaxially grown using a process such as chemical vapor deposition (CVD), atomic layer deposition (ALD), vapor phase epitaxy (VPE), molecular beam epitaxy (MBE), or the like. In various embodiments, the fifth semiconductor layers 210 may be formed of a semiconductor material suitable for serving as channel regions of top GAA-FETs, such as silicon, silicon germanium, or the like. In some embodiments, the fifth semiconductor layers 210 may be formed of a Group IV-based material, a Group III-V-based material, or a Group II-VI-based material.

In some embodiments, the fourth semiconductor layers 208 are formed of a fourth semiconductor material, and the fifth semiconductor layers 210 are formed of a fifth semiconductor material different from the fourth semiconductor material. The fourth semiconductor materials and the fifth semiconductor materials may be materials having a high-etch selectivity to one another. As such, the fourth semiconductor layers 208 of the fourth semiconductor material may be removed without significantly removing the fifth semiconductor layers 210 of the fifth semiconductor material, thereby allowing the fifth semiconductor layers 210 to serve as channel regions of top GAA-FETs. In some embodiments, the fourth semiconductor layers 208 are silicon germanium and the fifth semiconductor layers 210 are pure silicon (Si) having an etch selectivity to silicon germanium. In some embodiments, the fourth semiconductor layers 208 are silicon germanium and the fifth semiconductor layers 210 are pure germanium (Ge) having an etch selectivity to silicon germanium. In some embodiments, the first semiconductor layers 202 and the fourth semiconductor layers 208 are formed of a same semiconductor material, and the second semiconductor layers 204 and the fifth semiconductor layers 210 are formed of a same semiconductor material.

In some embodiments, the third semiconductor layer 206 is formed of a semiconductor material having a high etch selectivity to the semiconductor materials in the first multi-layer stack 201 and in the second multi-layer stack 203. In some embodiments, the third semiconductor layer 206 has a greater germanium concentration (i.e., germanium atomic percentage) than the first and second semiconductor layers 202, 204, and the fourth and fifth semiconductors 208, 210. For example, the third semiconductor layer 206 is silicon germanium having a greater germanium concentration than the silicon germanium of the first semiconductor layers 202 and the fourth semiconductor layers 208.

In some embodiments, the second semiconductor layers 204 are formed of a different material than the fifth semiconductor layers 210, such that the subsequently formed NFET nanosheets include different materials than PFET nanosheets. In some embodiments, the second semiconductor layers 204 have a different thickness than the fifth semiconductor layers 210, such that the subsequently formed NFET nanosheets have a different sheet height than PFET nanosheets. In some embodiments, the thickness difference between the second semiconductor layers 204 and fifth semiconductor layers 210 is in a range from about 0.5 nm to about 5 nm. In some embodiments, the first semiconductor layers 202 have a different thickness than the fourth semiconductor layers 202, such that sheet spacing between the subsequently formed NFET nanosheets can be different than sheet spacing between the subsequently formed PFET nanosheets. In some embodiments, the thickness difference between the first semiconductor layers 202 and fourth semiconductor layers 208 is in a range from about 0.5 nm to about 5 nm.

A hard mask layer HM1 is formed over the second multi-layer stack 203 by, for example, depositing one or more hark mask materials (e.g., silicon nitride and/or silicon oxide) over the second multi-layer stack 203, followed by patterning the one or more hard mask materials into the hard mask layer HM1 by using suitable photolithography and etching techniques. The first multi-layer stack 201, the third semiconductor layer 206 and the second multi-layer stack 203 are then patterned in one or more etching steps by using the hard mask layer HM1 as an etch mask. The one or more etching steps etch trenches through the second multi-layer stack 203, the third semiconductor layer 206, the first multi-layer stack 201 and into the substrate 100, thereby forming a plurality of fin structures 207 extending protruding from the substrate 100. The etching may be any acceptable etch process, such as a reactive ion etch (RIE), neutral beam etch (NBE), the like, or a combination thereof. The etching may be anisotropic.

The fin structures 207 may be patterned by any suitable method. For example, the fin structures 207 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 207. While each of the fin structures 207 are illustrated as having a consistent width throughout, in other embodiments, the fin structures 207 may have tapered sidewalls such that a width of each of the fin structures 207 continuously increases in a direction towards the substrate 100. In such embodiments, each of the semiconductor layers 202, 204, 206 208, 210 may have a different width and be trapezoidal in shape.

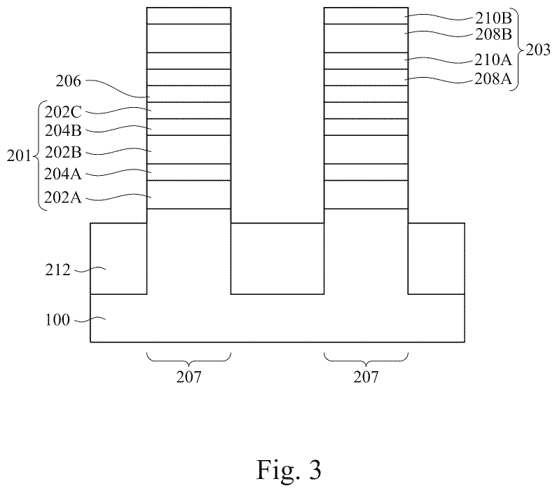

In FIG. 3, shallow trench isolation (STI) regions 212 are formed between adjacent fin structures 207. The STI regions 212 may be formed by depositing an insulation material over the substrate 100 and the fin structures 207. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the first multi-layer stack 201, the third semiconductor layer 206, and the second multi-layer stack 203. Although the insulation material is illustrated as a single layer, some embodiments may utilize multiple layers. For example, in some embodiments a liner (not separately illustrated) may first be formed along a surface of the substrate 100 and the fin structures 207. Thereafter, a fill material, such as those discussed above may be formed over the liner.

A removal process is then applied to the insulation material to remove excess insulation material over the second multi-layer stack 203. In some embodiments, a planarization process such as a chemical mechanical polish (CMP), an etch-back process, combinations thereof, or the like may be utilized. The planarization process exposes the second multi-layer stack 203 such that top surfaces of the second multi-layer stack 203 and the insulation material are level after the planarization process is complete.

The insulation material is then recessed to form the STI regions 212. The insulation material is recessed such that upper portions of fin structures 207 protrude from between neighboring STI regions 212. Further, the top surfaces of the STI regions 212 may have a flat surface as illustrated, a convex surface, a concave surface (such as dishing), or a combination thereof. The top surfaces of the STI regions 212 may be formed flat, convex, and/or concave by an appropriate etch. The STI regions 212 may be recessed using an acceptable etching process, such as one that is selective to the material of the insulation material (e.g., etches the material of the insulation material at a faster rate than the material of the fin structures 207). For example, an oxide removal using, for example, dilute hydrofluoric (dHF) acid may be used. After forming the STI regions 212, the hard mask layer HM1 is removed by using a selective etching process that selectively removes the hard mask layer HM1 without significantly etches fin structures 207 and the STI regions 212.

The process described above with respect to FIGS. 2-3 is just one example of how the fin structures 207 may be formed. In some embodiments, the fin structures 207 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 207. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 3, appropriate wells (not separately illustrated) may be formed in the fin structures 207. In some embodiments with different well types in different device regions (e.g., NFET region and PFET region), different implant steps may be achieved using a photoresist or other masks (not separately illustrated). For example, a photoresist may be formed over the fin structures 207 and the STI regions 212 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 207 and the STI regions 212 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal process may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

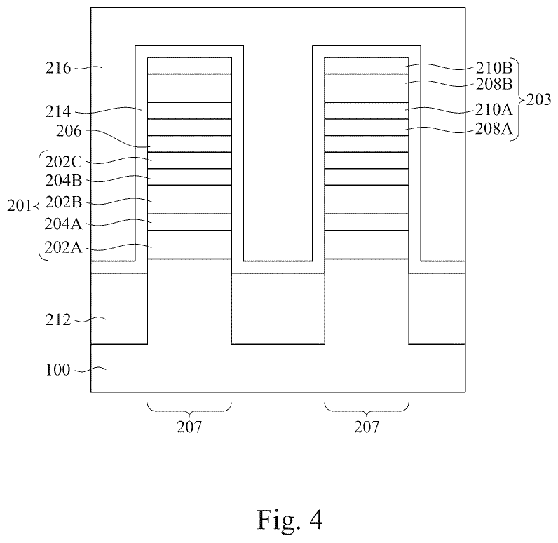

In FIG. 4, a dummy dielectric layer 214 is formed on the fin structures 207. The dummy dielectric layer 214 may be, for example, silicon oxide, silicon nitride, a combination thereof, or the like, and may be deposited or thermally grown according to acceptable techniques. A dummy gate layer 216 is formed over the dummy dielectric layer 214. The dummy gate layer 216 may be deposited over the dummy dielectric layer 214 and then planarized, such as by a CMP. The dummy gate layer 216 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 216 may be deposited by physical vapor deposition (PVD), CVD, sputter deposition, or other techniques for depositing the selected material. The dummy gate layer 216 may be made of other materials that have a high etching selectivity from the etching of isolation regions.

In FIGS. 5A and 5B, the dummy gate layer 216 and the dummy dielectric layer 214 are patterned to form dummy gates 220 and dummy gate dielectrics 218, respectively, by using suitable photolithography and etching processes. The dummy gates 220 cover respective channel regions of the fin structures 207. The dummy gates 220 may also have a lengthwise direction substantially perpendicular to the lengthwise direction of respective fin structures 207.

In FIGS. 6A and 6B, gate spacers 222 are formed on sidewalls of the dummy gate 220, and fin spacers 224 are formed on opposite sidewalls of the fin structure 207. For example, a spacer material layer is deposited on the substrate 100. The spacer material layer may be a conformal layer that is subsequently patterned to form gate spacers 222 and fin spacers 224. In the illustrated embodiment, a spacer material layer is disposed conformally on top and sidewalls of the dummy gates 220 and the fin structures 207. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gates 220 and the fin structures 207 using suitable deposition processes. An anisotropic etching process is then performed on the deposited spacer material layer to expose portions of the fin structures 207 not covered by the dummy gates 220 (e.g., over the source/drain regions of the fin structures 207). Portions of the spacer material layer directly above the dummy gates 220 and the fin structures 207 may be completely removed by this anisotropic etching process. Portions of the spacer material layer on sidewalls of the dummy gates 220 and dummy gate dielectrics 218 may remain, forming gate sidewall spacers, which are denoted as gate spacers 222. Another portions of the spacer material on sidewall of the fin structures 207 may remain, forming fin sidewall spacers, which are denoted as fin spacers 224.

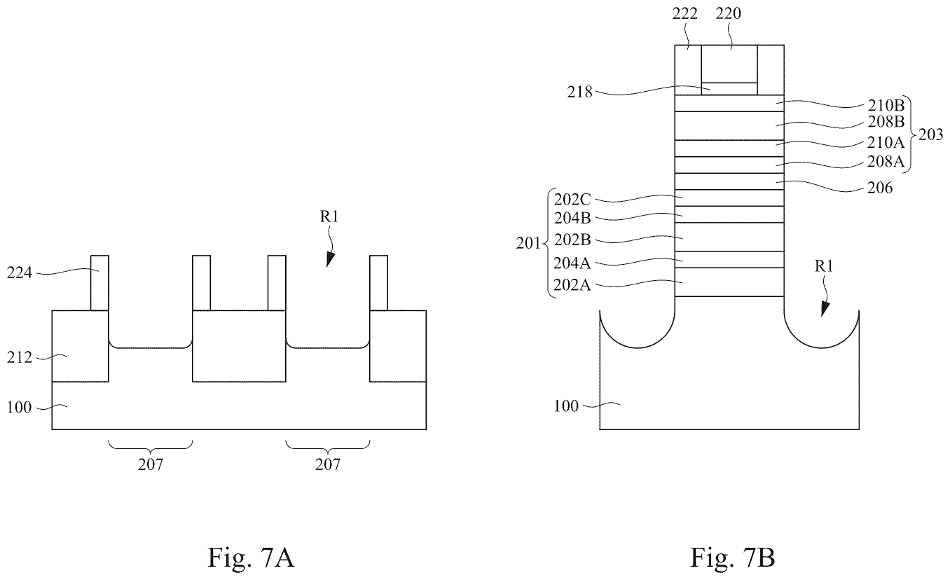

In FIGS. 7A and 7B, exposed portions of the fin structure 207 that extend laterally beyond the gate spacers 222 (e.g., in source/drain regions S/D of the fin structure 207) can be etched by using, for example, an anisotropic etching process that uses the dummy gate structure 220 and the gate spacers 222 as an etch mask, resulting in source/drain recesses R1 into the fin structures 207. After the anisotropic etching, end surfaces of the first, second, third, fourth, and fifth semiconductor layers 202, 204, 206, 208, 210, and respective outermost sidewalls of the gate spacers 222 are substantially aligned, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. When forming source/drain recesses R1, the anisotropic etching process may also etch the fin spacers 224, which in turn reduces the size of the fin spacers 224 and positions them on both sides of each source/drain recess R1. As a result, the fin spacers 224, initially sized to match the fin structure 207, become smaller due to the anisotropic etching, leaving the fin spacers 224 positioned to align with the source/drain recess R1.

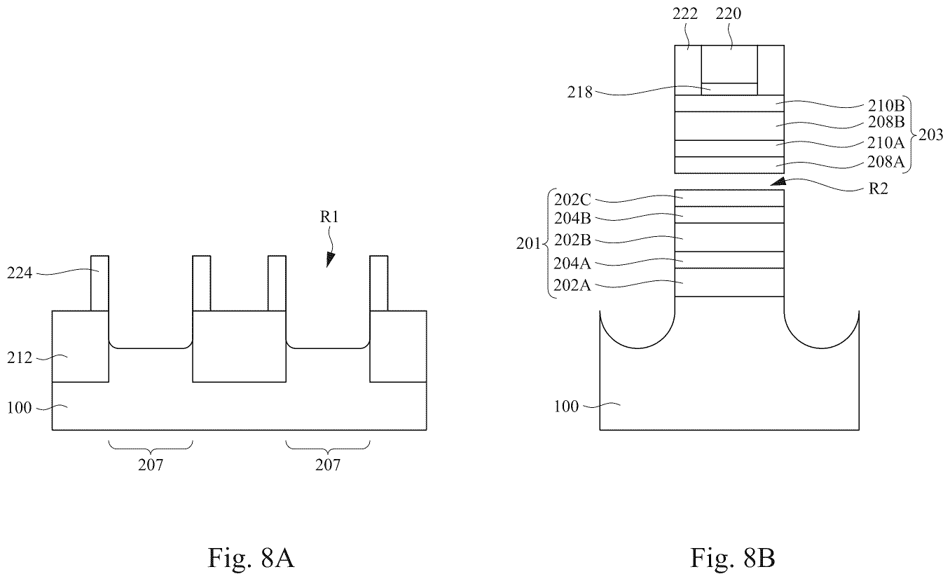

In FIGS. 8A and 8B, the third semiconductor layer 206 is removed by using a selective etching process that etches the third semiconductor layer 206 at a faster etch rate than etching the first multi-layer stack 201 and the second multi-layer stack 203, which in turn forms a nano-slot R2 between the topmost first semiconductor layer 202C of the first multi-layer stack 201 and the bottommost fourth semiconductor layer 208A of the second multi-layer stack 203. For selectively etching the high-Ge SiGe layer 206 without significantly etching the Si layers and low-Ge SiGe layers in the stacks 201 and 203, a suitable etchant such as a mixture of hydrogen peroxide and hydrofluoric acid can be used. Alternatively, a solution containing ammonium hydroxide and hydrogen peroxide may also be employed to achieve the desired selectivity.

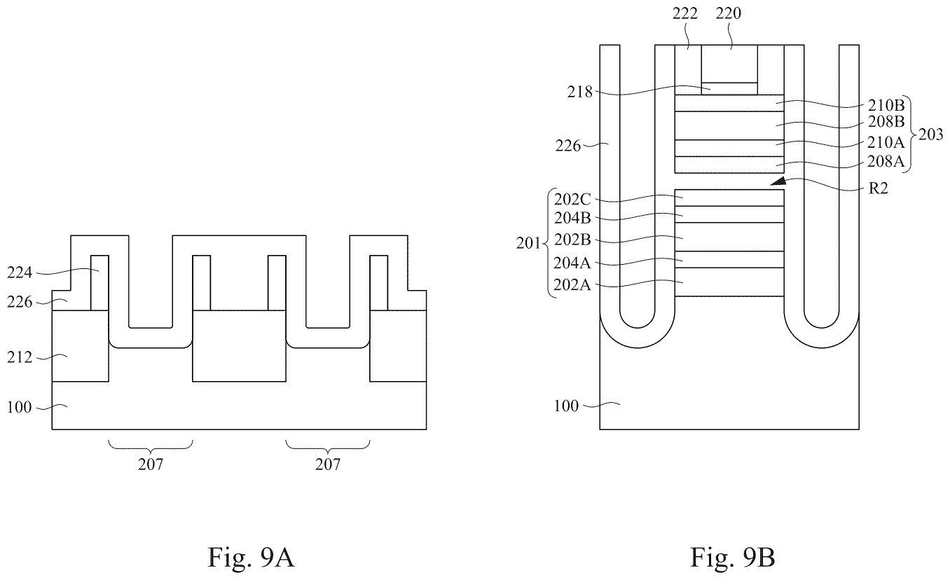

In FIGS. 9A and 9B, an isolation layer 226 is formed over the substrate 100 until the nano-slot R2 is overfilled with the isolation layer 226. The isolation layer 226 serve to isolate a subsequently formed bottom gate structure from a subsequently formed top gate structure, thereby mitigating the metal boundary effect. In some embodiments, the isolation layer 226 includes suitable dielectric materials, such as silicon nitride or silicon oxide. In some embodiments, the isolation layer 226 includes SiO₂, SiCO, fluorine-doped SiO₂, SiN, SiCN, SiCON, oxide, nitrogen, and carbon-based materials. In some embodiments, the isolation layer 226 is formed by using a suitable deposition technique such as ALD, CVD, or the like. In some embodiments, the isolation layer 226 may have a single-layer structure or a multi-layer structure including a plurality of dielectric layers.

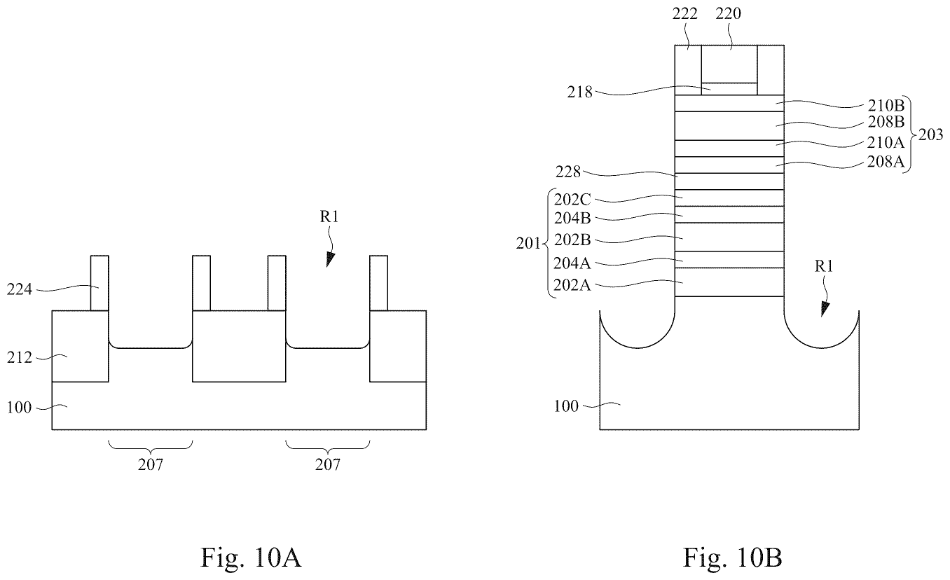

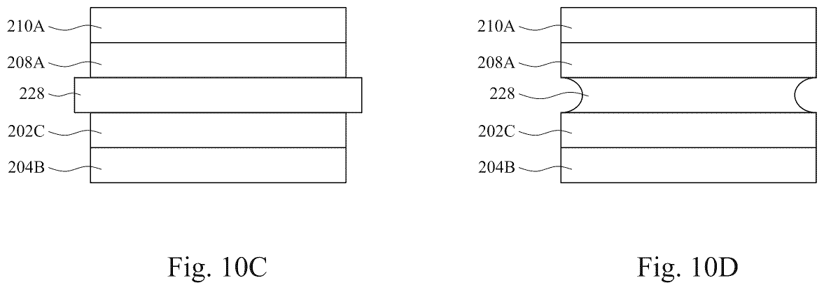

In FIGS. 10A and 10B, an etching process is performed on the isolation layer 226 to remove excess portions of the isolation layer 226 outside the nano-slot R2, while leaving a portion of the isolation layer 226 in the nano-slot R2 to serve as an isolation nanosheet (also referred to as isolation nanostructure) 228 disposed between the topmost first semiconductor layer 202C and the bottommost fourth semiconductor layer 208A. In some embodiments, the etching process is an anisotropic etching that removes the excess portions of the isolation layer 226 outside the nano-slot R2. Although outer sidewalls of the isolation nanosheet 228 are illustrated as being flush with sidewalls of the layers in the multi-layer stacks 201 and 203, the outer sidewalls of the isolation nanosheet 228 may extend beyond or be recessed from sidewalls of the layers in the multi-layer stacks 201 and 203, due to the etching process. For example, outer sidewalls of the isolation nanosheet 228 may extend beyond outer sidewalls of the layers 204B, 202C of the first multi-layer stack 201 and the layers 208A, 210A of the second multi-layer stack 203A, as illustrated in FIG. 10C. In some other embodiments, outer sidewalls of the isolation nanosheet 228 may be recessed from sidewalls of the layers 204B, 202C of the first multi-layer stack 201 and the layers 208A, 210A of the second multi-layer stack 203A, as illustrated in FIG. 10D.

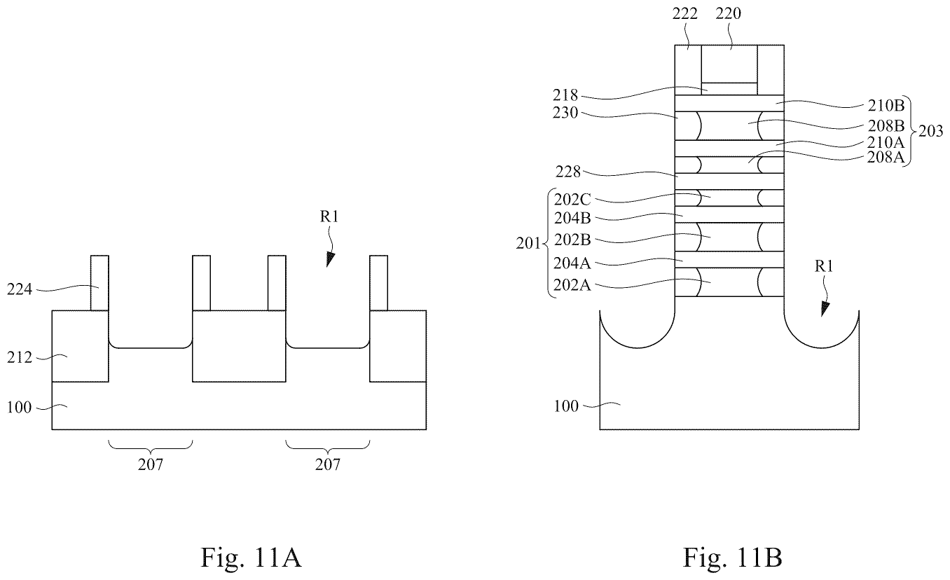

In FIGS. 11A and 11B, portions of sidewalls of the layers of the multi-layer stacks 201 and 203 formed of the first and fourth semiconductor materials (e.g., the first semiconductor layers 202 and the fourth semiconductor layers 208) exposed by the source/drain recesses R1 are etched to form sidewall recesses between corresponding second semiconductor layers 204 and between corresponding fifth semiconductor layers 210. Although sidewalls of the first and fourth semiconductor layers 202, 208 in the sidewall recesses are illustrated as being concave in FIG. 11B, the sidewalls may be straight or convex. The sidewalls may be etched using isotropic etching processes, such as wet etching or the like. In some embodiments in which the first and fourth semiconductor layers 202, 208 include, e.g., SiGe, and the second and fifth semiconductor layers 204, 210 include, e.g., Si or SiC, a dry etch process with tetramethylammonium hydroxide (TMAH), ammonium hydroxide (NH₄OH), or the like may be used to etch sidewalls of the first and fourth semiconductor layers 202, 208.

FIG. 11B further illustrates inner spacers 230 formed in the sidewall recesses formed in the first and fourth semiconductor layers 202, 208. The inner spacers 230 may be formed by depositing an inner spacer layer (not separately illustrated) over the substrate 100, followed by patterning the inner spacer layer into the inner spacers 230. The inner spacers 230 act as isolation features between subsequently formed source/drain regions and gate structure. As will be discussed in greater detail below, source/drain regions will be formed in the source/drain recesses R1, and the first and fourth semiconductor layers 202, 208 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second and fifth semiconductor layers 204 and 210, the outer sidewalls of the inner spacers 230 may extend beyond or be recessed from sidewalls of the second and fifth semiconductor layers 204 and 210. Moreover, although the outer sidewalls of the inner spacers 230 are illustrated as being straight in FIG. 11B, the outer sidewalls of the inner spacers 230 may be concave or convex. The inner spacer layer may be etched by an anisotropic etching process, such as RIE, NBE, or the like.

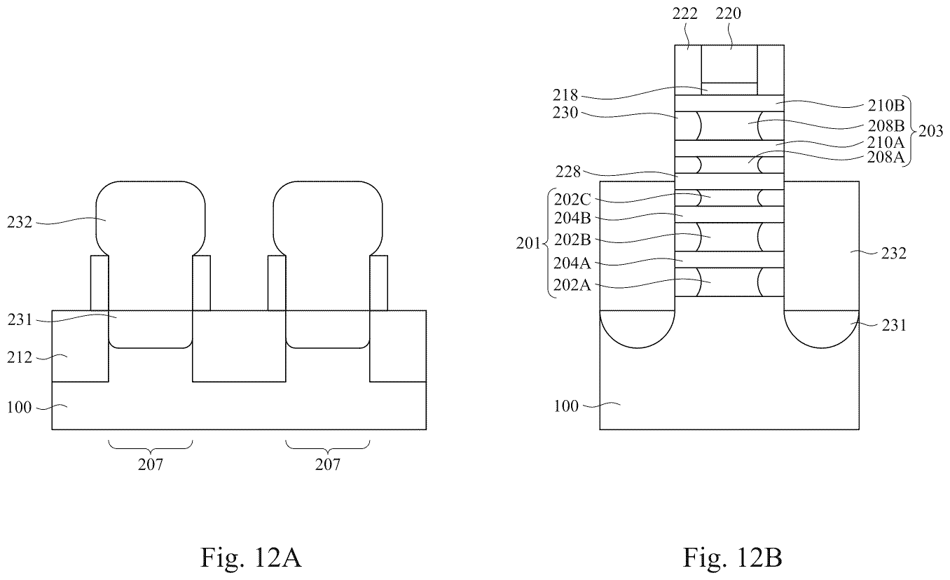

In FIGS. 12A-12B, epitaxial source/drain regions 232 are formed in lower portions of the source/drain recesses R1. In some embodiments, the source/drain regions 232 may exert stress on the second semiconductor layers 204, thereby improving device performance. As illustrated in FIG. 12B, the epitaxial source/drain regions 232 are formed in the source/drain recesses R1 such that a lower portion of each dummy gate 220 is disposed between respective neighboring pairs of the epitaxial source/drain regions 232. In some embodiments, the inner spacers 230 are used to separate the epitaxial source/drain regions 232 from the first semiconductor layers 202 by an appropriate lateral distance so that the epitaxial source/drain regions 232 do not short out with subsequently formed gates of the resulting bottom GAA-FETs. In some embodiments, prior to forming the epitaxial source/drain regions 232, an underlying layer 231 is formed in each source/drain recess R1. The underlying layer 231 may include, for example, an un-doped epitaxial layer and/or a bottom isolation layer, serving to isolate the epitaxial source/drain regions 232 from the substrate 100. In some embodiments where the underlying layer 231 is a bottom isolation layer, it can include a suitable dielectric material such as SiN, SiO₂, SiON, SiCN, SiCON, SiCO, or a high-k dielectric material (e.g., hafnium oxide, aluminum oxide, or the like). In some embodiments, the bottom isolation layer is a single-layer structure or a multi-layer structure.

In some embodiments, the epitaxial source/drain regions 232 may include any acceptable material appropriate for p-type GAA-FETs. For example, if the second semiconductor layers 204 are silicon, the epitaxial source/drain regions 232 may comprise materials exerting a compressive strain on the second semiconductor layers 204, such as silicon germanium, boron doped silicon germanium, germanium, germanium tin, or the like. In some embodiments, the epitaxial source/drain regions 232 may include any acceptable material appropriate for n-type GAA-FETs. For example, if the second semiconductor layers 204 are silicon, the epitaxial source/drain regions 232 may include materials exerting a tensile strain on the second semiconductor layers 204, such as silicon carbide, phosphorous doped silicon carbide, silicon phosphide, or the like.

In some embodiments, the epitaxial source/drain regions 232 are formed by a selective epitaxial growth (SEG) that selectively grows the crystalline material of the epitaxial source/drain regions 232 from end surfaces of the crystalline material of the second semiconductor layers 204. In some embodiments, end surfaces of the fifth semiconductor layers 210 can be covered by a mask layer to prevent the epitaxial source/drain regions 232 from unwantedly grown on the end surfaces of the fifth semiconductor layers 210. In some embodiments, forming the mask layer comprises forming a dummy material (e.g., spin-on carbon, SOC) overfilling the source/drain recesses R1, etching back the dummy material such that end surfaces of the fifth semiconductor layers 210 are exposed, depositing the mask layer over the end surfaces of the fifth semiconductor layers 210, followed by removing the dummy material. The mask layer is removed after the epitaxial source/drain regions 232 are formed.

The epitaxial source/drain regions 232 may be implanted with dopants to form source/drain regions, followed by an anneal process. The source/drain regions may have an impurity concentration of between about 1×10¹⁶ atoms/cm³ and about 1×10²¹ atoms/cm³. The n-type and/or p-type impurities for source/drain regions may be any of the impurities previously discussed. In some embodiments, the epitaxial source/drain regions 232 may be in situ doped during epitaxial growth. In some embodiments where the epitaxial source/drain regions 232 are doped with an n-type dopant (e.g., phosphorus, arsenic, antimony), the bottom GAA-FETs can serve as n-type transistors. In some embodiments where the epitaxial source/drain regions 232 are doped with a p-type dopant (e.g., boron), the bottom GAA-FETs can serve as p-type transistors.

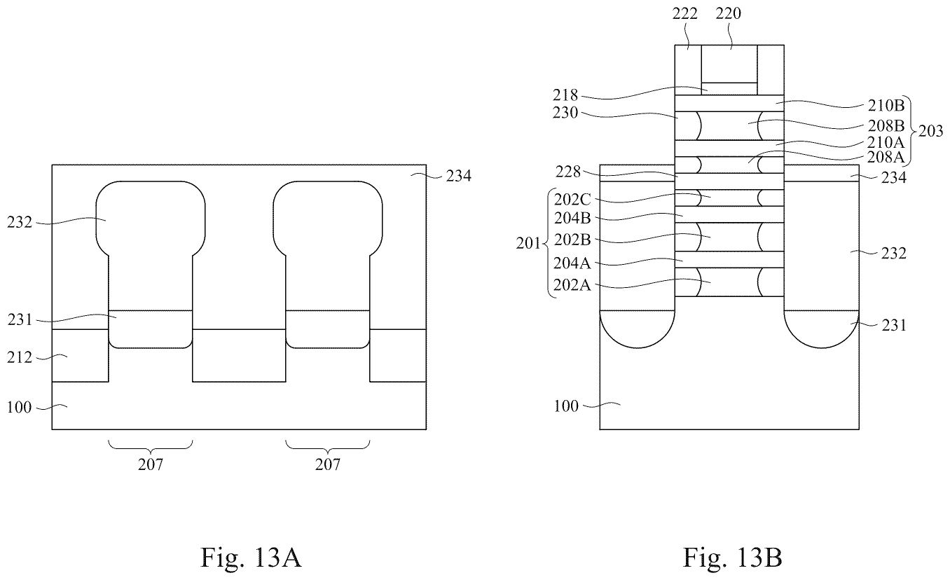

In FIGS. 13A and 13B, an interlayer dielectric (ILD) layer 234 can be formed over the substrate 100. In some embodiments, a contact etch stop layer (CESL) can be also formed prior to forming the ILD layer 234. In some examples, the CESL can include a silicon nitride layer, silicon oxide layer, a silicon oxynitride layer, and/or other suitable materials having a different etch selectivity than the ILD layer 234. In some embodiments, the CESL and the ILD layer 234 can be collectively referred to as an epitaxial isolation layer or a source/drain isolation layer, which serves to isolate the epitaxial source/drain regions 232 from subsequently formed source/drain regions of a top GAA-FET. In some embodiments, the ILD layer 234 can include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. In some embodiments, the ILD layer 234 may be made of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multi-layer structure including a plurality of dielectric layers.

Subsequently, the source/drain isolation layer 234 can be recessed, such that the upper portions of the source/drain recesses R1 may reappear. Specifically, an etching back process can be performed on the source/drain isolation layer 234. The etching back process, which targets the source/drain isolation layer 234, can be managed by controlling the duration of the process. This controlling is to ensure that the etching can halt at a predetermined level, such that the top surface of the etched-back source/drain isolation layer 234 can be higher than a top surface of the isolation nanosheet 228 and lower than a bottom surface of the bottommost fifth semiconductor layer 210A. Halting the etching at the target elevation can ensure that the subsequently formed epitaxial source/drain regions of top GAA-FETs can be formed on end surfaces of the all fifth semiconductor layers 210. In some embodiments, the etching back process can be an anisotropic dry etching process (e.g., a reactive-ion etching (RIE) process or an atomic layer etching (ALE) process), or other forms of plasma processing. That is, the etching back process can be anisotropic, where material is removed more in one direction (e.g., vertical direction) than in others. By way of example and not limitation, the etching back process may implement an etching gas, such as an oxygen-containing gas, a fluorine-containing gas (e.g., CF₄, SF₆, CH₂F₂, CHF₃, CH₃F and/or C₄F₈), a chlorine-containing gas (e.g., Cl₂ and/or BCl₃), a bromine-containing gas (e.g., HBr), an iodine-containing gas, other suitable gases and/or plasmas, and/or combinations thereof.

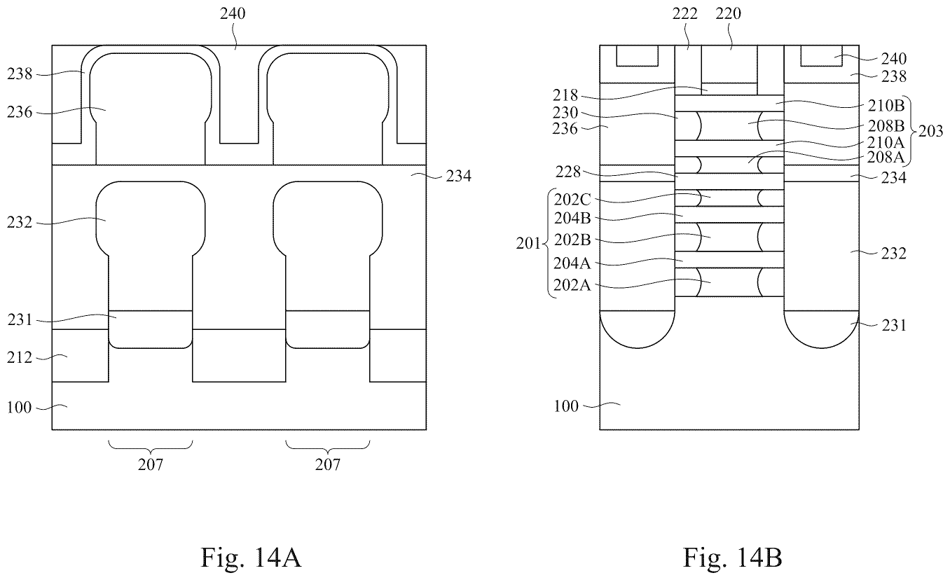

In FIGS. 14A and 14B, epitaxial source/drain regions 236 are epitaxially grown from the exposed end surfaces of the fifth semiconductor layers 210. In some embodiments, the source/drain regions 236 may exert stress on the fifth semiconductor layers 210, thereby improving device performance. As illustrated in FIG. 14B, the epitaxial source/drain regions 236 are grown from opposite end surfaces of the fifth semiconductor layers 210 such that each dummy gate 220 is disposed between respective neighboring pairs of the epitaxial source/drain regions 236. In some embodiments, the gate spacers 222 are used to separate the epitaxial source/drain regions 236 from the dummy gates 220, and the inner spacers 230 are used to separate the epitaxial source/drain regions 236 from the fourth semiconductor layers 208 by an appropriate lateral distance so that the epitaxial source/drain regions 236 do not short out with subsequently formed gates of the resulting top GAA-FETs.

In some embodiments, the epitaxial source/drain regions 236 may include any acceptable material appropriate for p-type GAA-FETs. For example, if the fifth semiconductor layers 210 are Si, the epitaxial source/drain regions 236 may comprise materials exerting a compressive strain on the fifth semiconductor layers 210, such as SiGe. In some embodiments, the epitaxial source/drain regions 236 may include any acceptable material appropriate for n-type GAA-FETs. For example, if the fifth semiconductor layers 210 are silicon, the epitaxial source/drain regions 236 may include materials exerting a tensile strain on the fifth semiconductor layers 210, such as silicon carbide, phosphorous doped silicon carbide, silicon phosphide, or the like.

In some embodiments, the epitaxial source/drain regions 236 are formed by a selective epitaxial growth (SEG) that selectively grows the crystalline material of the epitaxial source/drain regions 236 from end surfaces of the crystalline material of the fifth semiconductor layers 210. The epitaxial source/drain regions 236 may be implanted with dopants to form source/drain regions, followed by an anneal process. The source/drain regions may have an impurity concentration of between about 1×10¹⁶ atoms/cm³ and about 1×10²¹ atoms/cm³. The n-type and/or p-type impurities for source/drain regions may be any of the impurities previously discussed. In some embodiments, the epitaxial source/drain regions 236 may be in situ doped during growth. In some embodiments where the epitaxial source/drain regions 236 are doped with a p-type dopant (e.g., boron), the top GAA-FETs can serve as p-type transistors. In some embodiments where the epitaxial source/drain regions 236 are doped with an n-type dopant (e.g., phosphorus, arsenic, antimony), the top GAA-FETs can serve as n-type transistors.

In some embodiments, the epitaxial source/drain regions 236 are of a conductivity type different from a conductivity type the epitaxial source/drain regions 232, and thus the top GAA-FETs are of a conductivity type different from a conductivity type of the bottom GAA-FETs, which enables the formation of a CFET structure. For example, the bottom epitaxial source/drain regions 232 are p-type source/drain regions, and the top epitaxial source/drain regions 236 are n-type source/drain regions separated from the bottom epitaxial source/drain regions 232 by the source/drain isolation layer 234.

Subsequently, an ILD layer 240 can be formed over the substrate 100. In some embodiments, a CESL 238 can be also formed prior to forming the ILD layer 240. In some examples, the CESL 238 can include a silicon nitride layer, silicon oxide layer, a silicon oxynitride layer, and/or other suitable materials having a different etch selectivity than the ILD layer 240. In some embodiments, the ILD layer 240 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. After depositing the CESL 238 and the ILD layer 240, a planarization process (e.g., CMP process) may be performed to remove excessive materials of the CESL 238 and the ILD layer 240 overlying the dummy gate 220, such that the dummy gate 220 gets exposed.

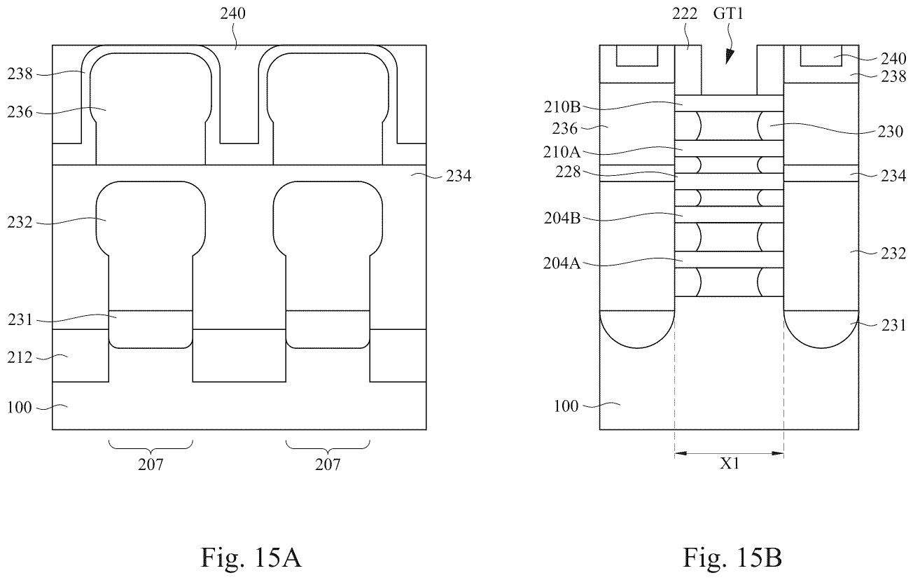

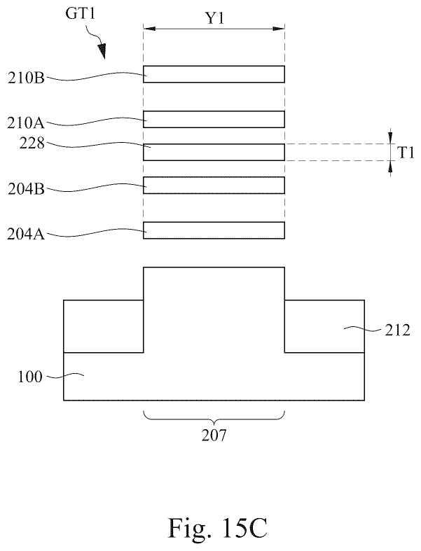

In FIGS. 15A-15C, the dummy gate 220 and the dummy gate dielectric 218 are removed in one or more etching steps, so that a gate trench GT1 is formed between corresponding gate spacers 222. In some embodiments, the dummy gate 220 and the dummy gate dielectric 218 are removed by an anisotropic dry etch process. For example, the etching process may include a dry etch process using reaction gas(es) that selectively etch the dummy gate 220 at a faster rate than the gate spacers 222. Each gate trench GT1 exposes and/or overlies portions of second and fifth semiconductor layers 204, 210, which will serve as channel regions in subsequently completed bottom GAA-FET and top GEE-FET respectively. The second semiconductor layers 204 serving as the bottom channel regions are disposed between neighboring pairs of the bottom epitaxial source/drain regions 232. The fifth semiconductor layers 210 serving as the top channel regions are disposed between neighboring pairs of the top epitaxial source/drain regions 236. During the removal, the dummy gate dielectric 218 may be used as an etch stop layer when the dummy gate 220 are etched. The dummy gate dielectric 218 may then be removed after the removal of the dummy gate 220.

Next, the first semiconductor layers 202 and the fourth semiconductor layers 208 exposed in the gate trenches GT1 are removed by an isotropic etching process such as wet etching or the like using etchants which are selective to the materials of the first semiconductor layers 202 and the fourth semiconductor layers 208. Stated differently, the first semiconductor layers 202 and the fourth semiconductor layers 208 are removed by using a selective etching process that etches the first semiconductor layers 202 and the fourth semiconductor layers 208 at a faster etch rate than it etches the second semiconductor layers 204 and fifth semiconductor layers 210, thus forming spaces between adjacent two of the second and fifth semiconductor layers 204 and 210 (also referred to as sheet-to-sheet spaces if the second and fifth semiconductor layers 204 and 210 are nanosheets). This step can be referred to as a channel release process. At this interim processing step, the spaces between adjacent two of the second and fifth semiconductor layers 204 and 210 may be filled with ambient environment conditions (e.g., air, nitrogen, etc). In some embodiments, the second and fifth semiconductor layers 204 and 210 can be referred to as nanostructures such as nanosheets, nanowires, nanoslabs, nanorings having nano-scale size (e.g., a few nanometers), depending on their geometry. For example, the second semiconductor layers 204 can be referred to as bottom nanosheets, and the first semiconductor layers 210 can be referred to as top nanosheets. For example, in some embodiments second and fifth semiconductor layers 204 and 210 may be trimmed to have a substantial rounded shape (i.e., cylindrical) due to the selective etching process for completely removing the first and fourth semiconductor layers 202 and 208. In that case, the resultant second and fifth semiconductor layers 204 and 210 can be called nanowires.

In embodiments in which the first and fourth semiconductor layers 202 and 208 include, e.g., SiGe, and the second and fifth semiconductor layers 204 and 210 include, e.g., Si or SiC, tetramethylammonium hydroxide (TMAH), ammonium hydroxide (NH₄OH) or the like may be used to remove the first and fourth semiconductor layers 202 and 208. In some embodiments, both the channel release step and the previous step of laterally recessing first and fourth semiconductor layers 202 and 208 (i.e., the step as illustrated in FIGS. 11A-11B) use a selective etching process that etches first and fourth semiconductor layers 202 and 208 (e.g., SiGe) at a faster etch rate than etching second and fifth semiconductor layers 204 and 210 (e.g., Si), and therefore these two steps may use the same etchant chemistry in some embodiments. In this case, the etching time/duration of channel release step is longer than the etching time/duration of the previous step of laterally recessing first and fourth semiconductor layers 202 and 208, so as to completely remove the sacrificial first and fourth semiconductor layers 202 and 208.

As illustrated in FIG. 15B, the isolation nanosheet 228 has a first dimension X1 substantially the same as the dimension of bottom nanosheets 204 and top nanosheets 210 that extend between the source/drain regions. As illustrated in FIG. 15C, the isolation nanosheet 228 has a second dimension Y1 substantially the same as the dimension of bottom nanosheets 204 and top nanosheets 210 that measured in a longitudinal direction of the gate trench GT1 (i.e., longitudinal direction of subsequently formed gate structures). In some embodiments, the second dimension Y1 is greater than the first dimension X1. In some embodiments, the second dimension Y1 is less than the first dimension X1. In some embodiments, the isolation nanosheet 228 has a thickness T1 measured in a vertical direction. The thickness T1 is less than the first dimension X1 and/or the second dimension Y1. In some embodiments, the thickness T1 of the isolation nanosheet 228 is less than a thickness of the bottom nanosheet 204 and/or a thickness of the top nanosheet 210. In some embodiments, the thickness T1 of the isolation nanosheet 228 is greater than a thickness of the bottom nanosheet 204 and/or a thickness of the top nanosheet 210. In some other embodiments, the thickness T1 of the isolation nanosheet 228 is equal to a thickness of the bottom nanosheet 204 and/or a thickness of the top nanosheet 210. In some embodiments, the thickness T1 of the isolation nanosheet 228 is in a range from about 0.5 nm to about 10 nm. If the thickness T1 of the isolation nanosheet 228 is excessively small (e.g., less than 0.5 nm), the isolation nanosheet 228 may be insufficient to mitigate the metal boundary effect. If the thickness T1 of the isolation nanosheet 228 is excessively large (e.g., greater than 10 nm), the isolation nanosheet 228 may complicate the subsequent gate metal deposition, due to the reduced spacing between the isolation nanosheet 228 and the bottom nanosheet 204B and the reduced spacing between the isolation nanosheet 228 and the top nanosheet 210A.

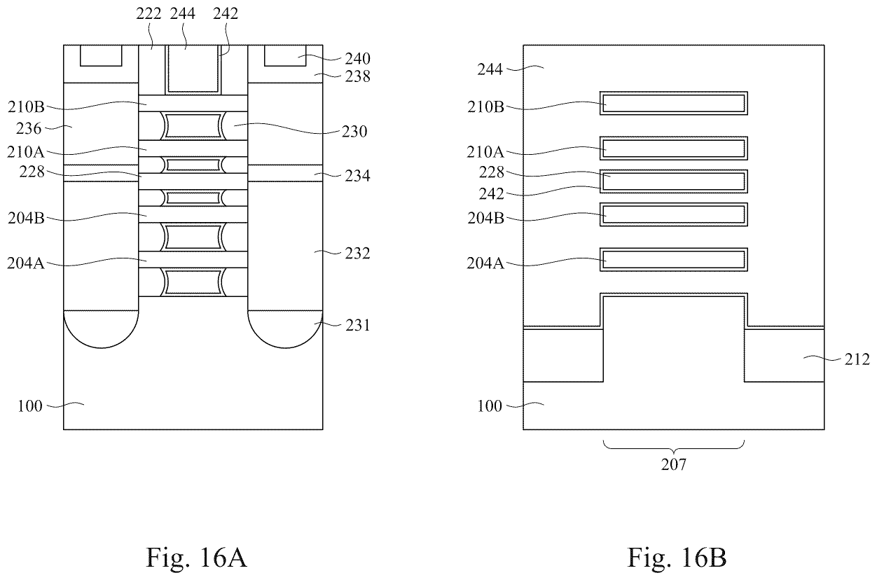

In FIGS. 16A-16B, a first gate dielectric layer 242 is formed in the gate trench GT1 to surround each of the bottom nanosheets 204, the isolation nanosheet 228, and top nanosheets 210 suspended in the gate trench GT1 by using a suitable deposition technique (e.g., CVD or ALD), and a first metal gate structure 244 is formed filling the gate trench GT1 by using suitable deposition techniques (e.g., CVD or ALD). After depositing materials of the first metal gate structure 244 in the gate trench GT1, a CMP process is performed on the first metal gate structure 244 and the first gate dielectric layer 242 until the ILD layer 240 is exposed.

In some embodiments, the first gate dielectric layer 242 includes an interfacial layer and a high-k gate dielectric layer. In some embodiments, the interfacial layer may include silicon oxide. In some embodiments, the high-k gate dielectric layer has a dielectric constant greater than a dielectric constant of SiO₂ (about 3.9). The high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the first metal gate structure 244 includes one or more metal layers. For example, the first metal gate structure 244 may include one or more work function metal layers stacked one over another and a fill metal filling up a remainder of gate trenches GT1. The one or more work function metal layers in the first metal gate structure 244 provide a suitable work function for the bottom GAA-FET. For a p-type GAA FET, the first metal gate structure 244 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. For an n-type GAA FET, the first metal gate structure 244 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. In some embodiments, the fill metal in the first metal gate structure 244 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

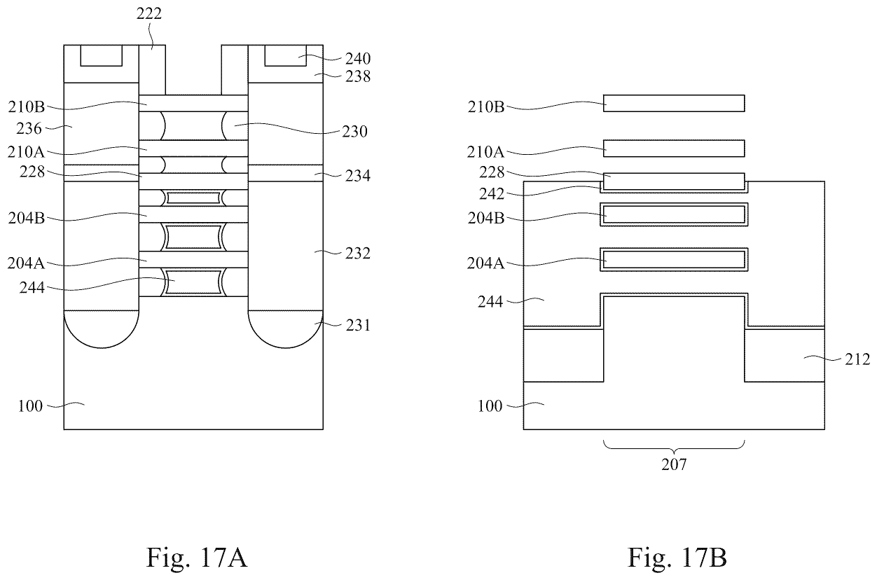

In FIGS. 17A and 17B, the first metal gate structure 244 is etched back such that a top surface of the first metal gate structure 244 falls below a top surface of the isolation nanosheet 228. In some embodiments, the etching back process may include one or more dry etching processes, wet etching processes, other suitable processes (e.g., reactive ion etching), and/or combinations thereof. In some embodiments, the etching back is a selective etching process that selectively etches the first metal gate structure 244 at a faster etch rate than etching other materials (e.g., material of the first gate dielectric layer 242), and thus the other materials (e.g., material of the first gate dielectric layer 242) can remain intact during the etching back process. In some embodiments, after the etching back process is complete, the first metal gate structure 244 has a top surface lower than a top surface of the isolation nanosheet 228 and higher than a bottom surface of the isolation nanosheet 228. In some embodiments, the first gate dielectric layer 242 is also etched back, such that the top nanosheets 210 and an upper portion of the isolation nanosheet 228 are exposed.

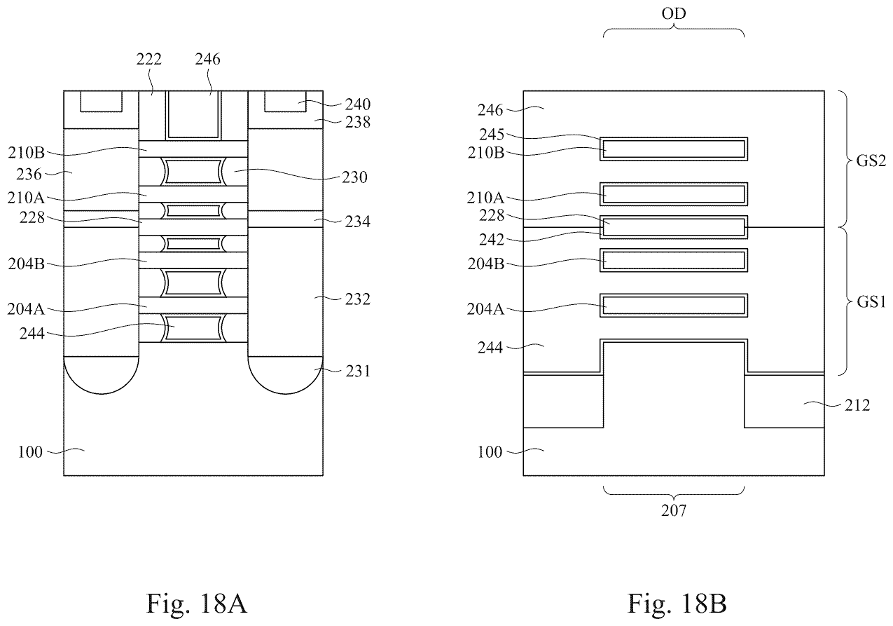

In FIGS. 18A and 18B, a second gate dielectric layer 245 is formed in the gate trench GT1 to surround each of the top nanosheets 210 suspended in the gate trench GT1 by using a suitable deposition technique (e.g., CVD or ALD), and a second gate structure 246 is formed filling the remaining portion of the gate trench GT1 by using suitable deposition techniques (e.g., CVD or ALD). After depositing materials of the second metal gate structure 246 in the gate trench GT1, a CMP process is performed on the second metal gate structure 246 until the ILD layer 240 is exposed.

In some embodiments, the second gate dielectric layer 245 includes an interfacial layer and a high-k gate dielectric layer. In some embodiments, the interfacial layer may include silicon oxide. In some embodiments, the high-k gate dielectric layer has a dielectric constant greater than a dielectric constant of SiO₂ (about 3.9). The high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. In some embodiments, the second gate dielectric layer 245 has a different high-k dielectric material and/or a different interfacial layer material than the first gate dielectric layer 242. In some embodiments, the second gate dielectric layer 245 has a different high-k dielectric thickness and/or a different interfacial layer thickness than the first gate dielectric layer 242.

In some embodiments, the second metal gate structure 246 includes one or more metal layers. For example, the second metal gate structure 246 may include one or more work function metal layers stacked one over another and a fill metal filling up a remainder of gate trenches GT1. The one or more work function metal layers in the second metal gate structure 246 provide a suitable work function for the bottom GAA-FET. For a p-type GAA FET, the second metal gate structure 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. For an n-type GAA FET, the second metal gate structure 246 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. In some embodiments, the fill metal in the second metal gate structure 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the first gate dielectric layer 242 and the first metal gate structure 244 collectively referred to as a first gate structure or a bottom gate structure GS1, and the second gate dielectric layer 245 and the second metal gate structure 246 collectively referred to as a second gate structure or a top gate structure GS2. In some embodiments, the second metal gate structure 246 includes one or more metal materials different than the first metal gate structure 244, because they serve as gates of opposite conductivity types. For example, when the bottom GAA-FET is a p-type transistor and the top GAA-FET is an n-type transistor, the first metal gate structure 244 may include more P-metal layers than the second metal gate structure 246, and the second metal gate structure 246 may include more N-metal layers than the first metal gate structure 244. When the bottom GAA-FET is an n-type transistor and the top GAA-FET is a p-type transistor, the first metal gate structure 244 may include more N-metal layers than the second metal gate structure 246, and the second metal gate structure 246 may include more P-metal layers than the first metal gate structure 244. Because of the compositional difference between the first and second metal gate structures 244 and 246, metal boundary effect may occur within the active region OD if the isolation nanosheet 228 is absent. However, the presence of the isolation nanosheet 228 within the active region OD ensures that the first metal gate structure 244 is spaced apart from the second metal gate structure 246, thereby mitigating the metal boundary effect.

As illustrated in FIG. 18B, the isolation nanosheet 228 does not overlap with the STI regions 212, and thus the first metal gate structure 244 is in contact with the second metal gate structure 246 over the STI regions 212. However, because the portions of the first and second metal gate structures 244 and 246 over the STI regions 212 exert less control over the bottom and top nanosheets 204 and 210, the metal boundary effect occurring over the STI regions 212 is negligible for the performance of bottom and top GAA-FETs. As illustrated in FIG. 18B, the first gate dielectric layer 242 wraps around four sides of the isolation nanosheet 228. In particular, top and bottom surfaces and lateral side surfaces of the isolation nanosheet 228 are all in contact with the first gate dielectric layer 242 (e.g., high-k material).

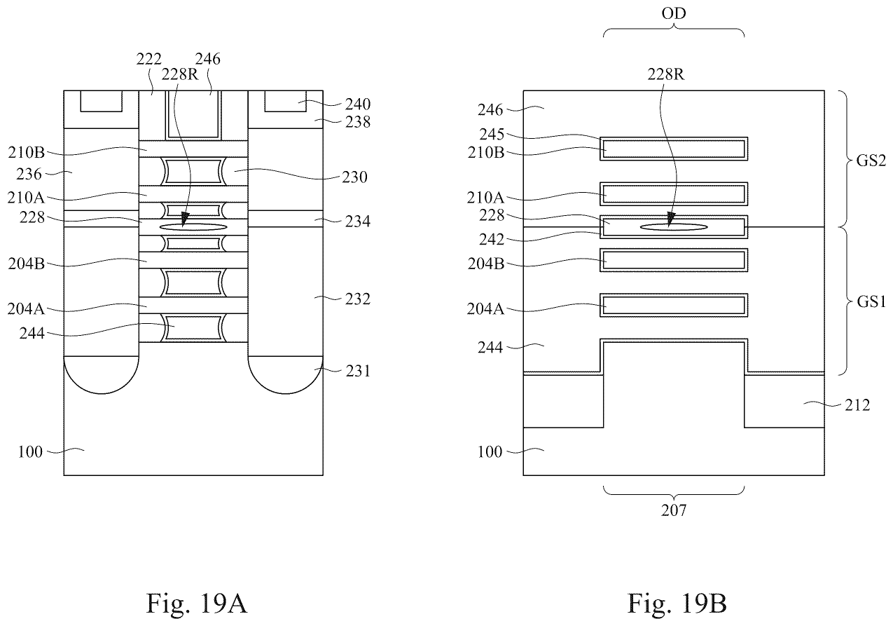

FIGS. 19A and 19B illustrate example cross-sectional views of GAA-FETs, in accordance with some embodiments. FIG. 19A illustrates reference cross-section C-C illustrated in FIG. 1 that extends in a direction of current flow between source/drain regions. FIG. 19B illustrates reference cross-section A-A illustrated in FIG. 1 that extends through a gate region along a longitudinal axis of the gate region. The structure illustrated in FIGS. 19A and 19B is the same as that shown in FIGS. 18A and 18B, except that the isolation nanosheet 228 includes an airgap 228R within the isolation nanosheet 228. The airgap 228R is an unfilled void resulting from the deposition process of forming the isolation nanosheet 228 into the small nano-slot R. For example, process conditions of the deposition process (e.g., ALD or CVD) can be controlled to form the airgap 228R in the isolation nanosheet 228.

To form the airgap 228R, process parameters in the ALD or CVD process such as temperature, pressure, and precursor flow rates can be finely tuned to create a non-conformal deposition. This non-conformal deposition results in the formation of unfilled void or airgap 228R within the deposited dielectric material of the isolation nanosheet 228. The inclusion of an airgap 228R within the isolation nanosheet 228 offers several benefits. For example, the airgap 228R significantly reduces the dielectric constant of the isolation nanosheet 228, thereby decreasing parasitic capacitance. In some embodiments as illustrated in FIG. 19A, the airgap 228R vertically overlaps with the bottom nanosheets 204 and the top nanosheets 210. Moreover, the air gap 228 may further laterally extend such that it vertically overlaps with the inner spacers and the gate spacers 222.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. Another advantage is that the metal boundary effect arising from different metal compositions in bottom and top gates of a CFET structure can be mitigated, by using a dielectric isolation nanosheet disposed between the bottom and top gates. Another advantage is that the parasitic capacitance can be reduced by forming an airgap within the dielectric isolation nanosheet. Yet another advantage is that fabrication of the dielectric isolation nanosheet is compatible with the CFET fabrication processing.

In some embodiments, a method comprises following steps. A first multi-layer stack is formed over a substrate. The first multi-layer stack comprises first semiconductor layers and second semiconductor layers alternating with the first semiconductor layers. A third semiconductor layer is formed over the first multi-layer stack. A second multi-layer stack is formed over the third semiconductor layer. The second multi-layer stack comprises fourth semiconductor layers and fifth semiconductor layers alternating with the fourth semiconductor layers. The third semiconductor layer is replaced with an isolation nanostructure. The isolation nanostructure has a bottom surface in contact with a topmost one of the first semiconductor layers and a top surface in contact with a bottommost one of the fourth semiconductor layers. The first semiconductor layers and fourth semiconductor layers are removed, such that the top surface and the bottom surface of the isolation nanostructure are exposed. A first gate structure is formed surrounding the first semiconductor layers. A second gate structure is formed surrounding the fifth semiconductor layers. The first gate structure and the second gate structure collectively surround the isolation nanostructure. In some embodiments, the second gate structure comprises a different metal material than the first gate structure, and the second gate structure comprises a different dielectric material than the first gate structure. In some embodiments, the isolation nanostructure has an airgap. In some embodiments, the first gate structure comprises a first gate dielectric layer in contact with a bottom surface of the isolation nanostructure, and the second gate structure comprises a second gate dielectric layer in contact with a top surface of the isolation nanostructure. In some embodiments, the second gate dielectric layer has a different material than the first gate dielectric layer. In some embodiments, the first gate dielectric layer is further in contact with a lower portion of a side surface of the isolation nanostructure, and the second gate dielectric layer is further in contact with an upper portion of the side surface of the isolation nanostructure. In some embodiments, a gate metal of the first gate structure has a top surface lower than a top surface of the isolation nanostructure and higher than a bottom surface of the isolation nanostructure. In some embodiments, the method further includes forming first epitaxial regions on opposite sides of the second semiconductor layers, and forming second epitaxial regions on opposite sides of the fifth semiconductor layers. The second epitaxial regions are of a different conductivity type than the first epitaxial regions.

In some embodiments, a method includes forming a first semiconductor nanostructure over a substrate, forming an isolation nanostructure over the first semiconductor nanostructure, forming a second semiconductor nanostructure over the isolation nanostructure, forming a first gate structure surrounding the first semiconductor nanostructure, and forming a second gate structure surrounding the second semiconductor nanostructure. The isolation nanostructure comprises a bottom surface and a top surface respectively in contact with a gate dielectric layer of the first gate structure and a gate dielectric layer of the second gate structure. In some embodiments, the isolation nanostructure further comprises an unfilled void vertically between the first semiconductor nanostructure and the second semiconductor nanostructure. In some embodiments, the isolation nanostructure further comprises opposite sidewalls connecting the bottom and top surfaces of the isolation nanostructure, and each of the opposite sidewalls has a lower portion in contact with the gate dielectric layer of the first gate structure and an upper portion in contact with the gate dielectric layer of the second gate structure. In some embodiments, the method further comprises forming a first inner spacer between the bottom surface of the isolation nanostructure and the first semiconductor nanostructure, and forming a first source/drain region spaced apart from the first gate structure by the first inner spacer. In some embodiments, the method further comprises forming a second inner spacer between the top surface of the isolation nanostructure and the second semiconductor nanostructure, and forming a second source/drain region spaced apart from the second gate structure by the second inner spacer. In some embodiments, the first and second inner spacer are formed simultaneously. In some embodiments, the second source/drain region is of a different conductivity type than the first source/drain region.

In some embodiments, a device comprises a first semiconductor layer over a substrate, first source/drain regions on opposite sides of the first semiconductor layer, an isolation layer over the first semiconductor layer, a second semiconductor layer over the isolation layer, second source/drain regions on opposite sides of the second semiconductor layer, a first gate structure surrounding the first semiconductor layer and in contact with a bottom surface of the isolation layer, and a second gate structure surrounding the second semiconductor layer and in contact with a top surface of the isolation layer. The first source/drain regions are of a first conductivity type. The second source/drain regions are of a second conductivity type different from the first conductivity type. In some embodiments, the second gate structure has a different metal composition than the first gate structure. In some embodiments, the isolation layer has an airgap vertically between the first semiconductor layer and the second semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first multi-layer stack over a substrate, the first multi-layer stack comprising first semiconductor layers and second semiconductor layers alternating with the first semiconductor layers;
forming a third semiconductor layer over the first multi-layer stack;
forming a second multi-layer stack over the third semiconductor layer, the second multi-layer stack comprising fourth semiconductor layers and fifth semiconductor layers alternating with the fourth semiconductor layers;
replacing the third semiconductor layer with an isolation nanostructure, the isolation nanostructure having a bottom surface in contact with a topmost one of the first semiconductor layers and a top surface in contact with a bottommost one of the fourth semiconductor layers;
removing the first semiconductor layers and the fourth semiconductor layers, such that the top surface and the bottom surface of the isolation nanostructure are exposed;
forming a first gate structure surrounding the first semiconductor layers; and
forming a second gate structure surrounding the fifth semiconductor layers, wherein the first gate structure and the second gate structure collectively surround the isolation nanostructure.

2. The method of claim 1, wherein the second gate structure comprises a different metal material than the first gate structure.

3. The method of claim 1, wherein the second gate structure comprises a different dielectric material than the first gate structure.

4. The method of claim 1, wherein the isolation nanostructure has an airgap.

5. The method of claim 1, wherein the first gate structure comprises a first gate dielectric layer in contact with the bottom surface of the isolation nanostructure.

6. The method of claim 5, wherein the second gate structure comprises a second gate dielectric layer in contact with the top surface of the isolation nanostructure.

7. The method of claim 6, wherein the second gate dielectric layer has a different material than the first gate dielectric layer.

8. The method of claim 6, wherein the first gate dielectric layer is further in contact with a lower portion of a side surface of the isolation nanostructure, and the second gate dielectric layer is further in contact with an upper portion of the side surface of the isolation nanostructure.

9. The method of claim 1, wherein a gate metal of the first gate structure has a top surface lower than the top surface of the isolation nanostructure and higher than the bottom surface of the isolation nanostructure.

10. The method of claim 1, further comprising:
forming first epitaxial regions on opposite sides of the second semiconductor layers; and
forming second epitaxial regions on opposite sides of the fifth semiconductor layers, wherein the second epitaxial regions are of a different conductivity type than the first epitaxial regions.

11. A method, comprising:
forming a first semiconductor nanostructure over a substrate;
forming an isolation nanostructure over the first semiconductor nanostructure;
forming a second semiconductor nanostructure over the isolation nanostructure;
forming a first gate structure surrounding the first semiconductor nanostructure; and
forming a second gate structure surrounding the second semiconductor nanostructure, wherein the isolation nanostructure comprises a bottom surface and a top surface respectively in contact with a gate dielectric layer of the first gate structure and a gate dielectric layer of the second gate structure.

12. The method of claim 11, wherein the isolation nanostructure further comprises an unfilled void vertically between the first semiconductor nanostructure and the second semiconductor nanostructure.

13. The method of claim 11, wherein the isolation nanostructure further comprises opposite sidewalls connecting the bottom and top surfaces of the isolation nanostructure, and each of the opposite sidewalls has a lower portion in contact with the gate dielectric layer of the first gate structure and an upper portion in contact with the gate dielectric layer of the second gate structure.

14. The method of claim 11, further comprising:
forming a first inner spacer between the bottom surface of the isolation nanostructure and the first semiconductor nanostructure; and
forming a first source/drain region spaced apart from the first gate structure by the first inner spacer.

15. The method of claim 14, further comprising:
forming a second inner spacer between the top surface of the isolation nanostructure and the second semiconductor nanostructure; and
forming a second source/drain region spaced apart from the second gate structure by the second inner spacer.

16. The method of claim 15, wherein the first and second inner spacer are formed simultaneously.

17. The method of claim 15, wherein the second source/drain region is of a different conductivity type than the first source/drain region.

18. A device, comprising:
a first semiconductor layer over a substrate;
first source/drain regions on opposite sides of the first semiconductor layer, the first source/drain regions being of a first conductivity type;
an isolation layer over the first semiconductor layer;
a second semiconductor layer over the isolation layer;
second source/drain regions on opposite sides of the second semiconductor layer, the second source/drain regions being of a second conductivity type different from the first conductivity type;
a first gate structure surrounding the first semiconductor layer and in contact with a bottom surface of the isolation layer; and
a second gate structure surrounding the second semiconductor layer and in contact with a top surface of the isolation layer.

19. The device of claim 18, wherein the second gate structure has a different metal composition than the first gate structure.

20. The device of claim 18, wherein the isolation layer has an airgap vertically between the first semiconductor layer and the second semiconductor layer.
